(19) United States
(12) Patent Application Publication
(10) Pub. No.: US 2013/0149445 A1
(43) Pub. Date: Jun. 13, 2013

(54) METHOD FOR PRODUCING A STRONG BOND BETWEEN A POLYMER SUBSTRATE AND AN INORGANIC LAYER

(71) Applicants: Steffen Guenther, Dresden (DE); Bjoern Meyer, Dresden (DE)

(72) Inventors: Steffen Guenther, Dresden (DE); Bjoern Meyer, Dresden (DE)

(73) Assignee: FRAUNHOFER-GESELLSCHAFT ZUR FOERDERUNG DER ANGEWANDTEN FORSCHUNG E.V.

(21) Appl. No.: 13/817,863

(22) PCT Filed: Jun. 14, 2011
(86) PCT No.: PCT/EP2011/002916

§ 371 Date: Feb. 20, 2013

(30) Foreign Application Priority Data
Oct. 20, 2010 (DE) 10 2010 048 984.0

(51) Int. Cl. C23C 14/22

(52) U.S. Cl. CPC C23C 14/22
USPC 427/248.1; 204/192.14

(57) ABSTRACT

The invention relates to a method for producing a firm bond between a polymer substrate and an inorganic layer, wherein the substrate surface is exposed to a precursor before the deposition of the inorganic layer which is to be produced by means of a PVD process.

The invention relates to a method, with which an inorganic layer exhibiting a high bonding strength can be deposited on a polymer substrate.

### BACKGROUND ART

Various materials are provided with thin layers in order to adapt their surface properties. In so doing, the bulk properties of the materials of interest are often not changed. One important aspect of such coatings is the bonding strength of the layers applied on the substrate material. If the substance classes of the substrate materials and the layer materials are radically different from each other or largely inert systems are present, it can be difficult to obtain a sufficient bonding strength between the substrate and the layer applied thereon.

This problem can be circumvented by energetically activating the substrate surfaces. Furthermore, it is possible to apply thin interlayers that exhibit a bonding strength that is just as good on the substrate as with the layer that is to be applied thereon. The use of chromium or more specifically layers that contain chromium, such as NiCr alloys, is used, for example, when coating polyimide substrates with copper [K. J. Blackwell et al., Enhancement of Chromium-to-Polyimide Adhesion by Oxygen DC Glow Treatment Prior to Roll-Sputter Seeding. In: 35th Annual Technical Conference Proceedings, Society of Vacuum Coaters, 1992, pages 279-283]. The disadvantage of this approach lies in the metallic character of the adhesion promoter layer. An adaptation to the copper and polyimide materials to be bonded in terms of their mechanical properties does not take place. The abrupt transition from a metal to a polymer often represents a breaking-point.

It is known to energetically activate polymer substrates of polypropylene by means of a corona or plasma preliminary treatment. At the same time radicals are produced on the surface, which radicals can enter into chemical bonds, for example, with metal atoms and, in so doing, make sure that the metal layers on the substrate will exhibit a very good bonding strength. In this method for enhancing the bonding strength, the substrate material is selectively damaged. As a result, chain breaks in the polymer structure and a surface layer of decomposition products that may form on the substrate have to be tolerated, so that there is only a narrow process window for the layer deposition process [H. Morgner et al., High Speed In-Line Treatment of Plastic Webs for Vacuum Coating. In: 42nd Annual Technical Conference Proceedings, Society of Vacuum Coaters, 1999, pages 460-464]. Even in the case of this technology an adaptation of the mechanical properties of substrate and layer does not take place.

An additional method for changing the properties at substrate surfaces is the selective melting and re-solidification of a substrate on its surface through an energy input by means of an ultraviolet light laser. The result of this approach is an amorphization of the substrate surface that leads to an increase in the bonding strength of layers that are subsequently deposited [D. J. McClure et al., Adhesion Promotion Technique for Coatings on PET, PEN and PI. In: 43rd Annual Technical Conference Proceedings, Society of Vacuum Coaters, 2000, pages 342-346].

All of the known technologies require a complex method for achieving the bonding strength. First of all, electrical systems are required in order to carry out the said deposition processes of the interlayers. Secondly, complex systems are used to generate a plasma discharge.

### OBJECT OF THE INVENTION

Therefore, the present invention is based on the technical problem of creating a method with which the drawbacks of the prior art are overcome. In particular, the object is to provide a method that can produce a strong bond between a polymer substrate and an inorganic layer. Furthermore, the method is to be technologically simple and economical to carry out.

This technical problem is solved by means of the subject matters exhibiting the features disclosed in claim 1. Additional advantageous embodiments of the invention will become apparent from the dependent claims.

The method according to the invention relates to a method, in which an inorganic layer is deposited on at least one surface region of a polymer substrate by means of a PVD [physical vapor deposition] process. Surprisingly it was found that an inorganic layer adheres particularly firmly to a polymer substrate, if prior to the deposition of the inorganic layer the polymer substrate is guided into a chamber, into which a precursor was admitted. At the same time it is not necessary to split up or to activate, as in the case of chemical vapor deposition, the precursor by process steps that accompany the process, such as the generation of a plasma or by heating, but rather the precursor is simply admitted only into the chamber. In the method according to the invention, precursor molecules are attached to the surface of the polymer substrate merely by means of adsorption. The term precursor is understood to mean, according to the invention, all those organic starting substances that are also used in the layer-forming method of chemical vapor deposition.

In a coating device with only one chamber, the method according to the invention can be carried out as follows. First, the polymer substrate is guided into the chamber, into which a precursor is admitted or has already been admitted. As a result, precursor molecules attach themselves to the surface of the polymer substrate by means of adsorption. Then the precursor molecules that did not attach themselves to the surface of the polymer substrate are removed from the chamber by, for example, venting and/or evacuating the chamber. After the pressure and gas relations that are necessary for the deposition process of the inorganic layer have been established in the chamber, the inorganic layer is deposited on the polymer substrate by means of a PVD [physical vapor deposition] process.

If the coating process is carried out by means of a multi-chamber system, there is no need to vent and/or evacuate the chamber containing the precursor, because after the surface of the polymer substrate has been loaded with a precursor in a first chamber so that precursor molecules have attached themselves to its surface by adsorption, this polymer substrate is then guided into a second chamber, in which the inorganic layer is deposited on the polymer substrate by means of a PVD process. In this case the substrate can be guided out of the first chamber into the second chamber directly in succession or additionally with a time delay. The term multi-chamber system is understood to mean in the context of this invention those systems that have at least two areas, in which different pressure and/or gas relations can be set. As an alternative, however, a multi-chamber system can also comprise at least two chambers that are spatially separated from each other, so that the spatial separation is not subject to a limitation. Thus, a polymer substrate can be loaded with the precursor, for example, at a first site inside a first chamber and then, following a conveying process to a second site in a second chamber, can be coated with an inorganic layer.

Since the precursor molecules in the method according to the invention are attached to the surface of a polymer substrate by adsorption, it is advantageous if the precursor is admitted into the chamber in the form of a gas or vapor. In order to adsorb precursor molecules on the surface of a polymer substrate, it is also advantageous to use a precursor that has a vapor pressure of less than 10⁵ Pa at 0 deg. C.

From the group of PVD techniques that are suitable for depositing the inorganic layer, evaporation and, in particular, also the magnetron sputtering process are two examples. These processes can be carried out in both a reactive mode, i.e. with the input of a reactive gas, or in a non-reactive mode. One advantage of the method according to the invention lies in the fact that this method can be carried out at both substrates that are moved and also at stationary substrates as well as in the so-called roll to roll process.

The reason for the high bonding strength of a composite resulting from the method according to the invention probably lies in the fact that the precursor molecules that are adsorbed on the surface of a polymer substrate are activated due to the impact of layer material particles; and, as a result, form reaction compounds with both the substrate surface as well as also with layer particles.

### EXEMPLARY EMBODIMENT

The invention is explained in detail below by means of exemplary embodiments. In a first exemplary embodiment the aim is to coat a polymer film, made of the material polyimide, with a 200 nm thick copper layer. The polymer film is available as a reel material. In a so-called roll to roll process the copper layer is deposited on the film by means of a magnetron sputtering process inside a single chamber system. According to the invention, the film is unwound, first of all, from a roller in a first passage and then guided through the one chamber, into which the precursor HMDSO [hexamethyldisiloxane] simultaneously flows in the form of a gas at a volumetric flow rate of 7 sccm. The precursor is neither split up nor activated by either a plasma or by means of heating. During the first passage through the chamber, molecules of the precursor are adsorbed on the surface of the polymer film. After the passage, the film is then wound onto another roller. Thereafter, the chamber is vented, and the gas and pressure relations that are required for the sputtering process inside the chamber follow as the next process steps. During a second passage through this chamber the polymer film is then coated with a 200 nm thick copper layer inside the chamber by means of a known magnetron sputtering process. In the case of the composite of a polyimide film and a copper layer that was produced according to the inventive method, a bonding strength of 6.2 N/cm could be demonstrated. On the other hand, in the case of a comparison coating method, in which the first passage through the chamber with the loading of the film surface with a precursor was omitted, but the separate coating process was carried out with the identical parameters, only an inadequate bonding strength having a value of 2 N/cm could be determined for the copper layer on the film.

In a second exemplary embodiment a 100 nm thick aluminum layer is deposited on a polymer film made of the material PEEK [polyether ether ketone] in a multi-chamber system by means of a magnetron sputtering process. In this case, too, the coating process is carried out by means of a roll to roll process, but only in a single passage. First the polymer film is guided through a first chamber, into which the precursor TEOS [tetraethylorthosilicate] having a flow rate of 6.5 sccm is admitted. In this case, too, there are no process-accompanying process steps that generate a splitting up or activating of the precursor. Inside the first chamber, molecules of the precursor are adsorbed at the surface of the film. Then the film is guided out of the first chamber into a second chamber, in which the gas and pressure relations for a known sputtering process are set. In this known sputtering process the 100 nm thick aluminum layer is deposited on the film by means of a magnetron. The resulting composite composed of a PEEK film and an aluminum layer could show a bonding strength of 13.8 N/cm. Even in the case of this example, a comparison coating was carried out. In the comparison coating the surface of the PEEK film was not exposed to a precursor-enriched environment before the coating process that was otherwise the same in all respects. The resulting composite that was produced therefrom showed only a bonding strength of less than 2 N/cm.

At this point it must be noted that the method according to the invention is not limited to just the polymer materials, the coating materials and the precursors that were disclosed in the exemplary embodiments. However, the effectiveness of the method according to the invention in terms of an enhanced bonding strength has already been demonstrated by means of a plurality of other materials and precursors. With respect to the polymer substrates some examples that can be named as representatives include PET [polyethylene terephthalate] and BOPP [biaxially oriented polypropylene]; with respect to the inorganic layer materials, oxides and nitrides; and with respect to the precursors, precursors that contain copper, titanium and/or aluminum. Furthermore, the loading of the surface of a polymer substrate with a precursor and the subsequent coating of the polymer substrate with an inorganic layer can be carried out at both a substrate that is moved as well as at a substrate that is not moved.

Thus the method according to the invention represents an option for producing the composite, composed of a polymer substrate and an inorganic layer, with a very high bonding strength with simple technical means, because the input of a precursor into a chamber is not accompanied by additional process steps, such as, for example, the generation of a plasma or the input of thermal energy.

1. A method for producing a strong bond between a polymer substrate and an inorganic layer, wherein the inorganic layer is deposited on at least one surface region of a polymer substrate by means of a PVD [physical vapor deposition] process, characterized by the following process steps:
a) guiding the substrate into a first chamber, into which a precursor is admitted without the process-accompanying process steps that cause the precursor to be split up or activated;
b) attaching precursor molecules by adsorption to the surface of the polymer substrate;
c) depositing the inorganic layer on the polymer substrate, after the precursor molecules, which did not attach themselves to the surface of the polymer substrate, were removed from the first chamber;
or
d) depositing the inorganic layer on the polymer substrate, after the polymer substrate was guided into a second chamber from the first chamber.

2. The method, as claimed in claim 1, characterized in that the inorganic layer is deposited by means of magnetron sputtering.

3. The method, as claimed in claim 2, characterized in that during the sputtering a magnetron target, which comprises a metal or a metal oxide, is atomized.

4. The method, as claimed in claim 3, characterized in that a copper or aluminum target is used.

5. The method, as claimed in claim 1, characterized in that the PVD (physical vapor deposition) process is run in a reactive mode.

6. The method, as claimed in claim 1, characterized in that a precursor in the form of a gas or vapor is used.

7. The method, as claimed in claim 6, characterized in that a precursor is used that has a vapor pressure of less than 10⁵ Pa at a temperature of 0 deg. C.

8. The method, as claimed in claim 1, characterized in that HMDSO [hexamethyldisiloxane], HMDSN [hexamethyldisilazane], and/or TEOS [tetraethylorthosilicate] is/are used as the precursor.
